(19) United States
(12) Patent Application Publication
(10) Pub. No.: US 2025/0271540 A1
(43) Pub. Date: Aug. 28, 2025

(54) VEHICULAR RADAR SENSOR MODULE

(71) Applicant: Magna Electronics Inc., Auburn Hills, MI (US)

(72) Inventor: Christian Mai, Grossostheim (DE)

(21) Appl. No.: 19/053,565

(22) Filed: Feb. 14, 2025

Related U.S. Application Data
(60) Provisional application No. 63/675,815, filed on Jul. 26, 2024.
(60) Provisional application No. 63/556,446, filed on Feb. 22, 2024.

(51) Int. Cl. G01S 7/02; G01S 13/931; H05K 7/14

(52) U.S. Cl. CPC G01S 7/027; G01S 13/931; H05K 7/1402

(57) ABSTRACT

A method for joining a vehicular radar sensor housing includes obtaining a first portion of a vehicular radar sensor housing and a second portion of the vehicular radar sensor housing. The first portion of the vehicular radar sensor housing includes a plastic joining surface and the second portion of the vehicular radar sensor housing includes a metal joining surface. The plastic joining portion of the first portion of the vehicular radar sensor housing is juxtaposed with the metal joining surface of the second portion of the vehicular radar sensor housing. The metal joining surface is heated, and heat is transferred from the metal joining surface to the plastic joining surface. The heat at least partially melts the plastic joining surface to thermally join the plastic joining surface and the metal joining surface.

### CROSS REFERENCE TO RELATED APPLICATIONS

The present application claims the filing benefits of U.S. provisional application Ser. No. 63/675,815, filed Jul. 26, 2024, and U.S. provisional application Ser. No. 63/556,446, filed Feb. 22, 2024, which are hereby incorporated herein by reference in their entireties.

### FIELD OF THE INVENTION

The present invention relates generally to a vehicle sensing system for a vehicle and, more particularly, to a vehicle sensing system that utilizes one or more radar sensors at a vehicle.

### BACKGROUND OF THE INVENTION

Use of radar sensors in vehicle sensing systems is common and known. Examples of such known systems are described in U.S. Pat. Nos. 9,146,898; 8,027,029 and/or 8,013,780, which are hereby incorporated herein by reference in their entireties.

### SUMMARY OF THE INVENTION

A method for joining a vehicular radar sensor housing includes obtaining a first portion of a vehicular radar sensor housing. The first portion of the vehicular radar sensor housing includes a plastic interface. The method includes obtaining a second portion of the vehicular radar sensor housing. The second portion of the vehicular radar sensor housing includes a metal interface. The method also includes juxtaposing the plastic interface of the first portion of the vehicular radar sensor housing and the metal interface of the second portion of the vehicular radar sensor housing. The method also includes heating the metal interface such that heat is transferred from the metal interface to the plastic interface. The heat at least partially melts the plastic interface to thermally join the plastic interface and the metal interface.

These and other objects, advantages, purposes and features of the present invention will become apparent upon review of the following specification in conjunction with the drawings.

### BRIEF DESCRIPTION OF THE DRAWINGS

FIG. 1 is a perspective view of a vehicle with a sensing system that incorporates a radar sensor;

FIG. 2 is a perspective view of a radar sensor housing joined using screws;

FIG. 3 is a perspective view of a radar sensor housing joined using thermal direct joining;

FIG. 4 is a perspective view and a section cut view of an axial join interface;

FIG. 5 is a perspective view and a section cut view of an axial and radial join interface;

FIG. 6 is an exploded view of a radar sensor;

FIG. 7 is a section cut view of thermal direct joining between a plastic housing and a metal housing; and

FIG. 8 is a section cut view of thermal direct joining between an antenna and a metal housing.

### DESCRIPTION OF THE PREFERRED EMBODIMENTS

A vehicle sensing system and/or driver assist system and/or driving assist system and/or object detection system and/or alert system operates to capture sensing data exterior of the vehicle and may process the captured data to detect objects at or near the vehicle and in the predicted path of the vehicle, such as to assist a driver of the vehicle or a control for an autonomous vehicle in maneuvering the vehicle in a forward or rearward direction. The system includes a processor that is operable to receive sensing data from one or more sensors and provide an output, such as an alert or control of a vehicle system.

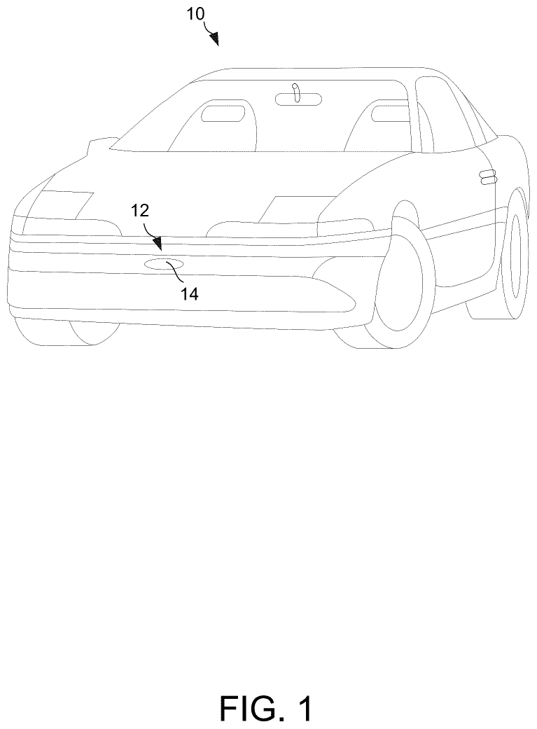

Referring now to the drawings and the illustrative embodiments depicted therein, a vehicle 10 (FIG. 1) includes a driving assistance system or sensing system 12 that includes at least one radar sensor unit, such as a forward facing radar sensor unit 14 (and the system may optionally include multiple exterior facing sensors, such as cameras, radar, or other sensors, such as a rearward facing sensor at the rear of the vehicle, one or more corner sensing sensors such as corner-mounted radar sensors, and/or a sideward/rearward facing sensor at respective sides of the vehicle), which sense regions exterior of the vehicle. The sensing system 12 includes a control or electronic control unit (ECU) that includes a data processor that is operable to process data captured by the radar sensor(s). The sensing system may also include a radar sensor that includes a plurality of transmitters that transmit radio signals via a plurality of antennas. The radar sensor also includes a plurality of receivers that receive radio signals via the plurality of antennas. The received radio signals are transmitted radio signals that are reflected from an object. The ECU or processor is operable to process the received radio signals to sense or detect the object that the received radio signals reflected from. The ECU or sensing system 12 may be part of a driving assist system of the vehicle, with the driving assist system controlling at least one function or feature of the vehicle (such as to provide autonomous driving control of the vehicle) responsive to processing of the data captured by the radar sensors. The data transfer or signal communication from the sensor to the ECU may comprise any suitable data or communication link, such as a vehicle network bus or the like of the equipped vehicle.

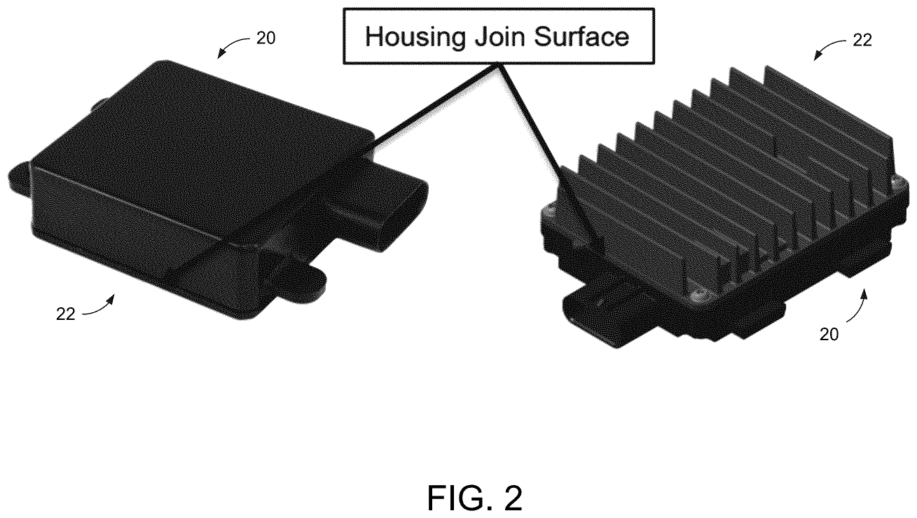

Current radar sensor housings are generally joined and/or assembled together using screws, adhesive/sealing, welding (e.g., laser, ultrasonic, etc.), or clips. In other words, a fastener (e.g., one or more screws or other threaded fasteners) is used to join portions of the radar sensor housing together. FIG. 2 illustrates a radar sensor housing with a first housing portion 20 joined with a second housing portion 22 via one of these methods (i.e., screws).

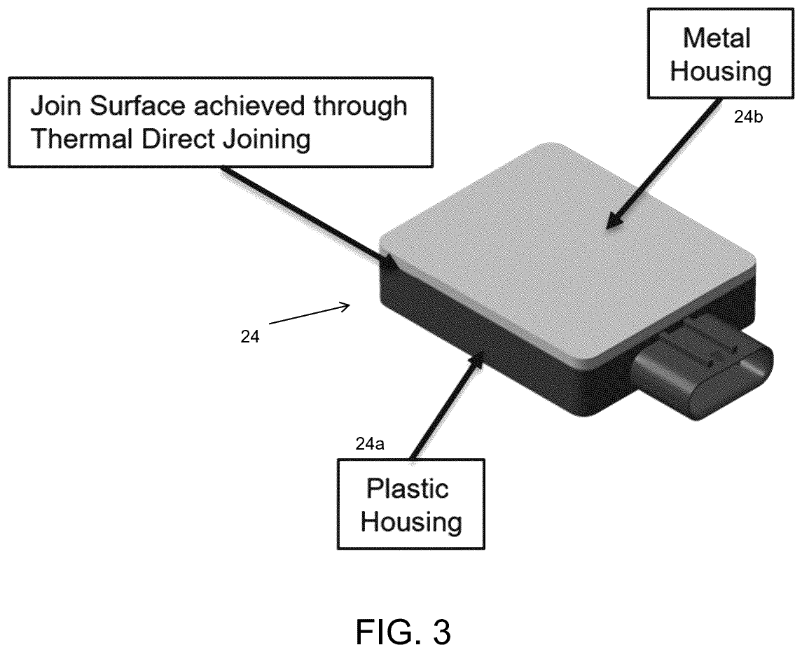

Referring now to FIG. 3, implementations herein instead include a radar sensor housing 24 joined using thermal direct joining to join two or more portions of the radar sensor housing 24. For example, the radar sensor housing 24 includes a first portion 24a that includes an at least partially plastic joining surface or interface and a second portion 24b that includes an at least partially metal joining surface or interface. The systems and methods herein include joining the plastic joining surface or interface of the first portion 24a to the metal joining surface or interface of the second portion 24b via thermal direct joining.

Thermal direct joining refers to the joining of metal and plastic portions or housings without the use of any additional materials such as adhesives, screws, clips, etc. To join the plastic housing portion 24a with the metal housing portion 24b, the metal portion may be treated at the contact surface (e.g., roughening, coating, etc.). After preparation, the joining surface of the metal housing is juxtaposed with or positioned at or placed in contact with the joining surface of the plastic housing, and the components may be pressed together. Heat is then applied to the metal surface (e.g., via inductive heating by generating, via application of an electromagnetic field at the component, eddy currents within the metal material to heat the component). The heating of the metal portion in contact with the plastic portion slightly melts the plastic at the joining surface. After heating is completed, the joined housings are cooled passively or actively to secure the metal housing portion 24b and the plastic housing portion 24a together. The cooled sensor housing may be disposed or installed into or at a vehicle as part of a vehicular radar sensing system.

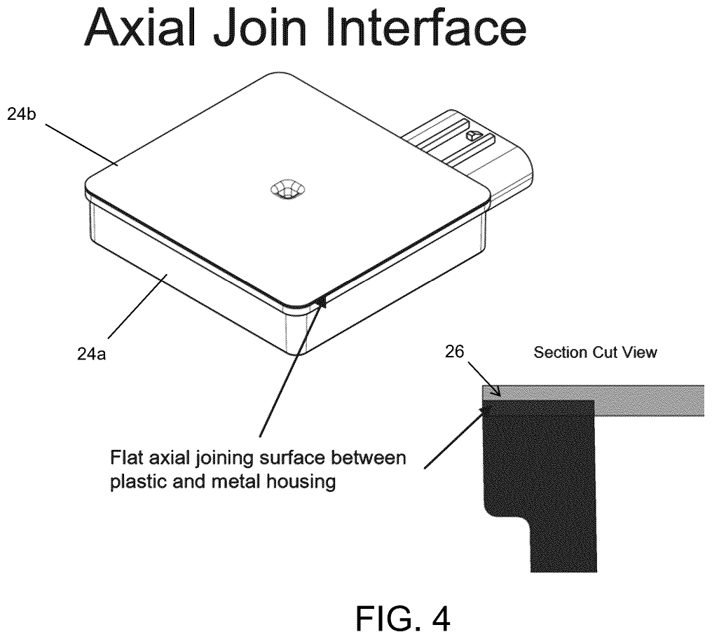

Optionally, the radar sensor includes an axial join interface. As shown in FIG. 4, the radar sensor includes a flat axial joining surface 26 between the plastic portion 24a of the housing 24 and the metal portion 24b of the housing 24. For example, the sides of the housing 24 are plastic, and the top of the housing 24 is metal. That is, the flat axial joining surface may be between an upper edge of the sides of the plastic portion 24a of the housing 24 and a lower or bottom planar surface of the metal portion 24b of the housing 24. The metal portion 24b may comprise a top or cover of the housing 24.

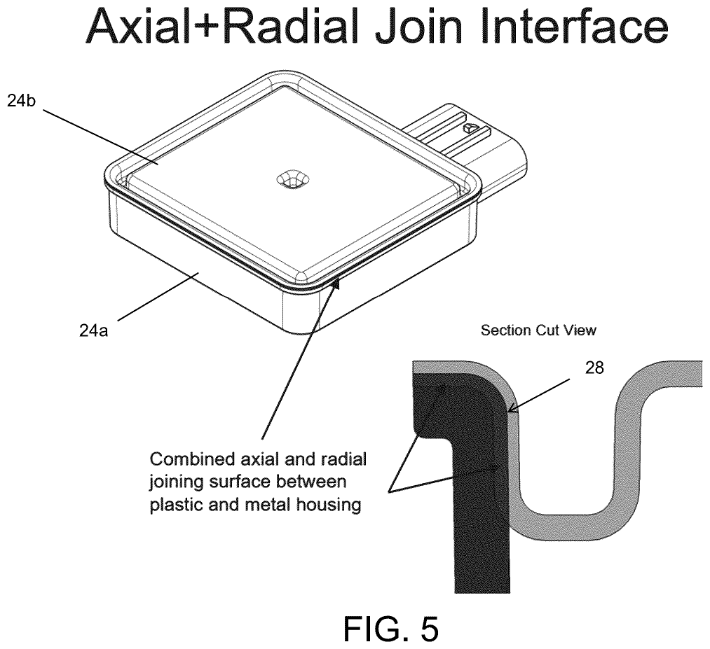

In some examples, and as shown in FIG. 5, the radar sensor includes an axial joining interface and a radial join interface. As also shown in FIG. 5, the radar sensor includes a combined axial and radial joining surface 28 between the plastic portion 24a of the housing 24 and the metal portion 24b of the housing 24. In the illustrated example, the metal portion 24b of the housing 24 includes an indentation or channel extending about a periphery region of the metal portion 24b to form a generally U-shaped portion of the metal portion 24b. A curved flange extends from an upper end of the U-shaped portion. The upper edge of the sides of the plastic portion 24a includes a rounded lip. When the metal portion 24b interfaces with the plastic portion 24a, a part of the U-shaped portion extends along and engages an inner surface of the sides of the plastic portion 24a, a portion of the curved flange extends along and engages the rounded lip and an end portion of the curved flange extends along and engages an upper flat portion of the upper edge of the sides of the plastic portion 24a.

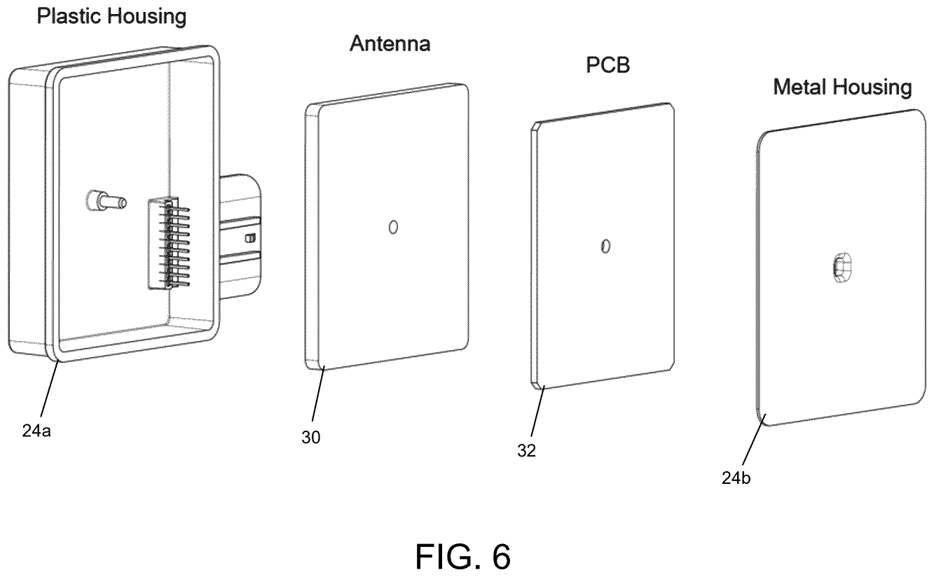

FIG. 6 illustrates an exemplary exploded view of the radar sensor. Here, the radar sensor includes an antenna 30 and a printed circuit board (PCB) 32 within the plastic housing portion 24a and the metal housing portion 24b. The plastic and metal housings may be different housings or different portions of the same housing. The plastic housing and metal housing, when joined, enclose the antenna 30 and PCB 32 within a cavity formed by the plastic housing portion 24a and the metal housing portion 24b.

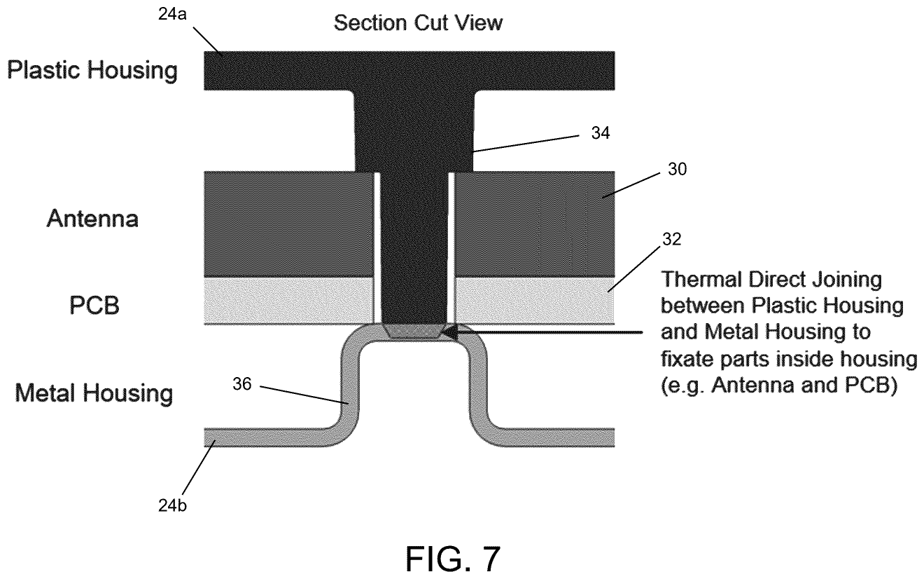

In some examples, and as shown in FIG. 7, thermal direct joining may be used to join the plastic housing portion 24a and the metal housing portion 24b to fix components (e.g., the antenna 30 and the PCB 32) within the housing 24. For example, the plastic portion 24a or the metal portion 24b of the housing 24 includes a support 34 such as a protrusion or pillar or column or other feature that at least partially extends into the cavity of the housing 24 and is joined using thermal direct joining with the other portion of the housing. In the illustrated example of FIG. 7, the plastic housing portion 24a includes the support 34 that extends within the interior portion of the housing 24 and through respective apertures or holes of the antenna 30 and the PCB 32. In this example, the metal housing portion 24b also includes an indent or other feature 36 that extends at least partially into the cavity to meet with the support 34 of the plastic portion 24a of the housing. During thermal direct joining, the feature 36 of the metal housing portion 24b heats and at least partially melts the support 34 to join the plastic housing portion 24a and the metal housing portion 24b.

The support 34 may pass through one or more components of the radar sensor to fix the components into place. Here, the support 34 extends from the plastic portion 24a of the housing, through the antenna 30 and PCB 32 (via a circular aperture in the antenna and PCB) and joins the metal portion 24b of the housing. Thus, the protrusion 34 of the plastic housing portion 24a may be received through a passageway of the antenna 30 and PCB 32 and may be pressed into engagement with the metal housing portion 24b, whereby the metal housing portion 24b may be heated (e.g., via induction) to join the protrusion 34 of the plastic housing portion 24a with the metal housing portion 24b with the antenna 30 and PCB 32 clamped or retained between the metal housing portion 24b and a flange of the plastic housing portion 24a.

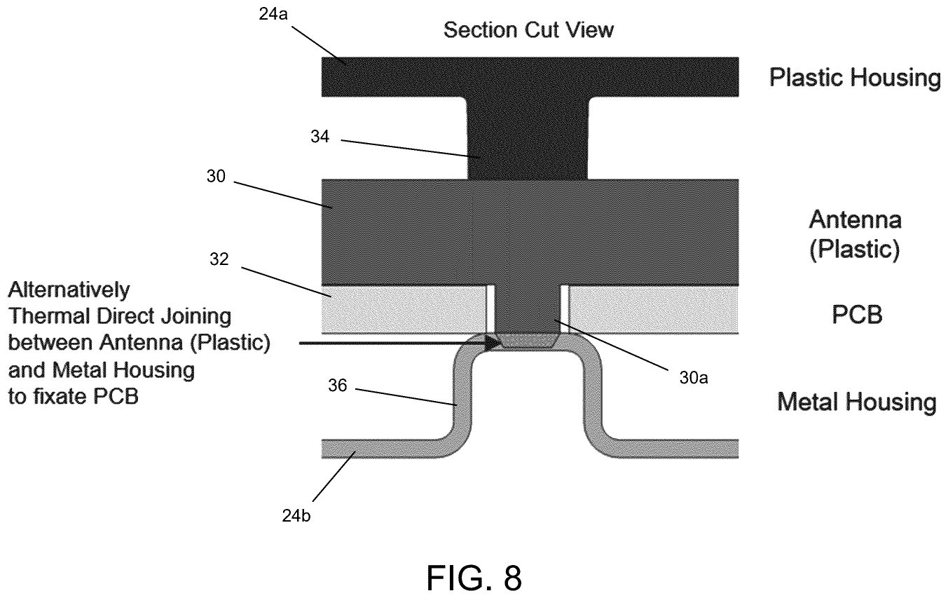

Alternatively, and as shown in FIG. 8, thermal direct joining may be used between a plastic portion of a component within the radar sensor (e.g., a plastic portion of the antenna) and the metal portion 24b of the housing. In the illustrated example of FIG. 8, the protrusion 34 from the plastic portion 24a of the housing provides support by extending to the antenna 30. The antenna 30 includes a protrusion or support 30a that extends through an aperture in the PCB 32 to join with the metal portion 24b of the housing via thermal direct joining. The protrusion 30a of the antenna 30 may engage and join to the support 36 of the metal housing portion 24b. This fixes the PCB 32 in place within the enclosure of the housing.

Optionally, other forms of thermal direct joining may be implemented to join the housings together. For example, laser heating and/or infrared heating may be used in addition to or as an alternative to induction heating.

The system may utilize sensors, such as radar sensors or imaging radar sensors or lidar sensors or the like, to detect presence of and/or range to objects and/or other vehicles and/or pedestrians. The sensing system may utilize aspects of the systems described in U.S. Pat. Nos. 10,866,306; 9,954,955; 9,869,762; 9,753,121; 9,689,967; 9,599,702; 9,575,160; 9,146,898; 9,036,026; 8,027,029; 8,013,780; 7,408,627; 7,405,812; 7,379,163; 7,379,100; 7,375,803; 7,352,454; 7,340,077; 7,321,111; 7,310,431; 7,283,213; 7,212,663; 7,203,356; 7,176,438; 7,157,685; 7,053,357; 6,919,549; 6,906,793; 6,876,775; 6,710,770; 6,690,354; 6,678,039; 6,674,895 and/or 6,587,186, and/or U.S. Publication Nos. US-2019-0339382; US-2018-0231635; US-2018-0045812; US-2018-0015875; US-2017-0356994; US-2017-0315231; US-2017-0276788; US-2017-0254873; US-2017-0222311 and/or US-2010-0245066, which are hereby incorporated herein by reference in their entireties.

The radar sensors of the sensing system each comprise a plurality of transmitters that transmit radio signals via a plurality of antennas, a plurality of receivers that receive radio signals via the plurality of antennas, with the received radio signals being transmitted radio signals that are reflected from an object present in the field of sensing of the respective radar sensor. The system includes an ECU or control that includes a data processor for processing sensor data captured by the radar sensors. The ECU or sensing system may be part of a driving assist system of the vehicle, with the driving assist system controlling at least one function or feature of the vehicle (such as to provide autonomous driving control of the vehicle) responsive to processing of the data captured by the radar sensors.

The radar sensor or sensors may be disposed at the vehicle so as to sense exterior of the vehicle. For example, the radar sensor may comprise a front sensing radar sensor mounted at a grille or front bumper of the vehicle, such as for use with an automatic emergency braking system of the vehicle, an adaptive cruise control system of the vehicle, a collision avoidance system of the vehicle, etc., or the radar sensor may be comprise a corner radar sensor disposed at a front corner or rear corner of the vehicle, such as for use with a surround vision system of the vehicle, or the radar sensor may comprise a blind spot monitoring radars disposed at a rear fender of the vehicle for monitoring sideward/rearward of the vehicle for a blind spot monitoring and alert system of the vehicle. Optionally, the radar sensor or sensors may be disposed within the vehicle so as to sense interior of the vehicle, such as for use with a cabin monitoring system of the vehicle or a driver monitoring system of the vehicle or an occupant detection or monitoring system of the vehicle. The radar sensing system may comprise multiple input multiple output (MIMO) radar sensors having multiple transmitting antennas and multiple receiving antennas.

Changes and modifications in the specifically described embodiments can be carried out without departing from the principles of the invention, which is intended to be limited only by the scope of the appended claims, as interpreted according to the principles of patent law including the doctrine of equivalents.

1. A method for assembling a vehicular radar sensor housing, the method comprising:
obtaining a first portion of a vehicular radar sensor housing, wherein the first portion of the vehicular radar sensor housing comprises a plastic interface;
obtaining a second portion of the vehicular radar sensor housing, wherein the second portion of the vehicular radar sensor housing comprises a metal interface;
juxtaposing the plastic interface of the first portion of the vehicular radar sensor housing and the metal interface of the second portion of the vehicular radar sensor housing; and
heating the metal interface, wherein heat is transferred from the metal interface to the plastic interface, and wherein the heat at least partially melts the plastic interface to thermally join the plastic interface and the metal interface.

2. The method of claim 1, wherein heating the metal interface comprises generating eddy currents within the metal interface.

3. The method of claim 1, wherein the vehicular radar sensor housing is not joined via any of the group consisting of (i) fasteners, (ii) adhesives, (iii) welding and (iv) clips.

4. The method of claim 1, wherein the method further comprises, after heating the metal interface, cooling the vehicular radar sensor housing.

5. The method of claim 4, wherein cooling the vehicular radar sensor housing comprises active cooling.

6. The method of claim 4, wherein the method further comprises, after cooling the vehicular radar sensor housing, disposing the vehicular radar sensor housing at a vehicle.

7. The method of claim 1, wherein the plastic interface and the metal interface are joined at an axial join interface.

8. The method of claim 1, wherein the plastic interface and the metal interface are joined at an axial and radial join interface.

9. The method of claim 1, wherein the vehicular radar sensor housing accommodates a printed circuit board (PCB).

10. The method of claim 9, wherein the first portion of the vehicular radar sensor housing comprises a protrusion that extends through the PCB to the second portion of the vehicular radar sensor housing to secure the PCB in place within a cavity formed by the vehicular radar sensor housing.

11. The method of claim 10, wherein the protrusion comprises the plastic interface.

12. The method of claim 10, wherein the vehicular radar sensor housing houses an antenna, and wherein the protrusion extends through the antenna.

13. A method for assembling a vehicular radar sensor housing, the method comprising:
obtaining a portion of a vehicular radar sensor housing, wherein the portion of the vehicular radar sensor housing comprises a metal interface;
obtaining a printed circuit board (PCB);
obtaining an antenna, wherein the antenna comprises a protrusion, and wherein the protrusion comprises a plastic interface;
disposing the antenna such that (i) the protrusion extends through the PCB to the portion of the vehicular radar sensor housing to secure the PCB in place between the antenna and the portion of the vehicular radar sensor housing and (ii) the plastic interface of the antenna is in contact with the metal interface of the portion of the vehicular radar sensor housing; and
heating the metal interface, wherein heat is transferred from the metal interface to the plastic interface, and wherein the heat at least partially melts the plastic interface to thermally join the plastic interface and the metal interface.

14. The method of claim 13, wherein heating the metal interface comprises generating eddy currents within the metal interface.

15. The method of claim 13, wherein the vehicular radar sensor housing is not joined via any of the group consisting of (i) fasteners, (ii) adhesives, (iii) welding and (iv) clips.

16. The method of claim 13, wherein the method further comprises, after heating the metal interface, cooling the vehicular radar sensor housing.

17. The method of claim 16, wherein the method further comprises, after cooling the vehicular radar sensor housing, disposing the vehicular radar sensor housing at a vehicle.

18. A method for assembling a vehicular radar sensor housing, the method comprising:
obtaining a first portion of a vehicular radar sensor housing, wherein the first portion of the vehicular radar sensor housing comprises a protrusion, and wherein the protrusion comprises a plastic interface;
obtaining a second portion of the vehicular radar sensor housing, wherein the second portion of the vehicular radar sensor housing comprises a metal interface;
obtaining a printed circuit board (PCB);
obtaining an antenna;
disposing the antenna and the PCB within a cavity formed by the vehicular radar sensor housing such that (i) the protrusion extends through the antenna and the PCB to the second portion of the vehicular radar sensor housing and (ii) the plastic interface of the protrusion is in contact with the metal interface of the second portion of the vehicular radar sensor housing; and
heating the metal interface, wherein heat is transferred from the metal interface to the plastic interface, and wherein the heat at least partially melts the plastic interface to thermally join the plastic interface and the metal interface.

19. The method of claim 18, wherein heating the metal interface comprises generating eddy currents within the metal interface.

20. The method of claim 18, wherein the vehicular radar sensor housing is not joined via any of the group consisting of (i) fasteners, (ii) adhesives, (iii) welding and (iv) clips.

21. The method of claim 18, wherein the method further comprises, after heating the metal interface, cooling the vehicular radar sensor housing.

22. The method of claim 21, wherein the method further comprises, after cooling the vehicular radar sensor housing, disposing the vehicular radar sensor housing at a vehicle.
